(19) United States
(12) Patent Application Publication
(10) Pub. No.: US 2019/0168486 A1
(43) Pub. Date: Jun. 6, 2019

(54) Heat Dissipation Sheet Having Excellent Heat Dissipation Characteristics and Manufacturing Method Therefor

(71) Applicant: SOLUETA, Ansan-si, Gyeonggi-do (KR)

(72) Inventors: Eui Hong MIN, Seongnam-si, Gyeonggi-do (KR); Dong-Won LEE, Pyeongtaek-si, Gyeonggi-do (KR); Min Seong KIM, Ansan-si, Gyeonggi-do (KR); Hyun Soo NOH, Hwaseong-si, Gyeonggi-do (KR); Hye Jin HAN, Ansan-si, Gyeonggi-do (KR)

(73) Assignee: SOLUETA, Ansan-si, Gyeonggi-do (KR)

(21) Appl. No.: 16/087,221

(22) PCT Filed: Mar. 23, 2016
(86) PCT No.: PCT/KR2016/002897

§ 371 Date: Jan. 11, 2019

(30) Foreign Application Priority Data
Mar. 22, 2016 (KR) 10-2016-0034285

(51) Int. Cl. B32B 9/04; B32B 9/00; B32B 15/20; B32B 37/24; B32B 38/00; H05K 7/20; H05K 9/00

(52) U.S. Cl. CPC B32B 9/041; B32B 9/007; B32B 15/20; B32B 37/24; B32B 38/0012; B32B 38/0036; B32B 2457/00; H05K 9/0081; B32B 2037/243; B32B 2250/02; B32B 2307/302; B32B 2311/12; B32B 2313/04; H05K 7/20509

(57) ABSTRACT

The present invention has been proposed to resolve the above-described problems, and it is an objective of the present invention to provide a heat dissipation sheet with excellent heat dissipation properties, which has a specific porosity, exhibits excellent horizontal heat conductivity, and exhibits an excellent effect in peel strength, and a manufacturing method thereof.

### TECHNICAL FIELD

The present invention relates to a heat dissipation sheet with excellent heat dissipation properties and a manufacturing method thereof, and more particularly, to a heat dissipation sheet with excellent heat dissipation properties, which has a specific porosity, exhibits excellent horizontal heat conductivity, and exhibits an excellent effect in peel strength, and a manufacturing method thereof.

### BACKGROUND ART

Generally, when an electronic product is driven, heat is generated inside an electronic device included in the electronic product. Further, when the generated heat is not discharged to the outside as quickly as possible, the heat may affect the electronic device, resulting in failure to perform an original function of the electronic device. Due to this heat, noise or malfunction may occur in peripheral parts or equipment, and the service life of the product may be shortened.

Particularly, as electronic products are aimed at high performance, high functionality, and being lightweight, short and small, occurrences of increased capacities of electronic devices and highly integrated electronic devices are inevitable. Thus, how effectively the heat generated from parts of these electronic products is released may be a key factor in the performance and quality of the products.

Conventionally, as a method for solving the above problems, a fin-fan cooling method, a Peltier cooling method, a water jet cooling method, an immersion cooling method, a heat pipe cooling method, and the like are used to remove heat generated from electronic devices. However, there is a demand for cooling devices and heat dissipation devices for the electronic devices suitable for the recent trend in which electronic products are becoming thinner and smaller in size.

Particularly, the use of notebooks and mobile phones has been expanding due to the recent development of the electronic communication industry, and since these products tend to be super lightweight and ultra-thin, there is a preference for removing heat by including heat dissipation sheets in these products.

Conventionally, electromagnetic interference (EMI) shielding heat shrinkable tapes, which are manufactured in a tape form for heat dissipation properties and use heat shrinkable tapes including a heat shrinkable layer and an EMI shielding layer, are disclosed. However, in the conventional structure, a heat dissipation layer includes an adhesive layer, and thus heat dissipation efficiency is decreased and a manufacturing process is complicated. Further, it is difficult to have a specific porosity, exhibit excellent horizontal heat conductivity, and exhibit an excellent effect in peel strength.

### PRIOR-ART DOCUMENTS

### Patent Documents

### (Patent Document 1) Korea Patent Publication No. 10-2014-009204 (Jan. 22, 2014)

### DISCLOSURE

### Technical Problem

The present invention has been proposed to resolve the above-described problems, and it is an objective of the present invention to provide a heat dissipation sheet with excellent heat dissipation properties, which has a specific porosity, exhibits excellent horizontal heat conductivity, and exhibits an excellent effect in peel strength, and a manufacturing method thereof.

### Technical Solution

According to an aspect of the present invention, there is provided a heat dissipation sheet with enhanced heat dissipation properties which includes a heat dissipation enhancing layer including carbon materials and a heat conductive base layer formed on one surface of the heat dissipation enhancing layer, and has a horizontal heat conductivity of 420 to 620 W/mK, wherein, the carbon material includes at least one selected from graphene and graphite.

According to one embodiment of the present invention, the heat dissipation enhancing layer may not include a binder resin

According to another embodiment of the present invention, the heat dissipation enhancing layer may have a thickness of 2 to 20 μm, and the heat conductive base layer may have a thickness of 13 to 40 μm.

According to still another embodiment of the present invention, the heat conductive base layer may include at least one selected from an electrolytic copper foil and a rolled copper foil.

According to another aspect of the present invention, there is provided a method of manufacturing a heat dissipation sheet having enhanced heat dissipation properties, including: a process of manufacturing a heat dissipation enhancing coating liquid including a carbon material, a binder resin, and a solvent; a process of applying the heat dissipation enhancing coating liquid on one surface of a heat conductive base layer to form a heat dissipation layer; a process of performing first calendering on the heat dissipation layer and the heat conductive base layer; a process of heat treating the first calendered heat dissipation layer and heat conductive base layer to form a heat dissipation enhancing layer and the heat conductive base layer; and a process of performing second calendering on the heat dissipation enhancing layer and the heat conductive base layer to manufacture the heat dissipation sheet.

According to one embodiment of the present invention, the binder resin may include a first urethane resin having a solid content of 28 to 32 wt % and a second urethane resin having a solid content of 34 to 38 wt %.

According to another embodiment of the present invention, the binder resin may include the first urethane resin and the second urethane resin in a weight ratio of 1:0.5 to 1:0.85.

According to still another embodiment of the present invention, the process of manufacturing the heat dissipation enhancing coating liquid may include: a process of mixing and stirring 80 to 120 parts by weight of a binder resin and 180 to 220 parts by weight of a solvent based on 100 parts by weight of a carbon material for 30 to 60 minutes to manufacture a mixed solution; and a process of stabilizing the mixed solution at a temperature of 20° C. to 30° C. for 30 to 60 minutes to manufacture the heat dissipation enhancing coating liquid.

According to still yet another embodiment of the present invention, the solvent may include toluene and ethyl acetate in a weight ratio of 1:0.7 to 1:1.4, and the heat conductive base layer may include at least one selected from an electrolytic copper foil and a rolled copper foil.

According to still yet another embodiment of the present invention, in the process of forming the heat dissipation layer, the heat dissipation layer may be formed such that a thickness of the heat dissipation layer is 1.2 to 2.0 times the thickness of the heat dissipation enhancing layer.

According to still yet another embodiment of the present invention, the heat dissipation enhancing layer may not include the binder resin

According to still yet another embodiment of the present invention, the first calendering may be performed at a temperature of 60° C. to 80° C. with a load of 35 to 45 tons, the heat treatment may be performed at a temperature of 400° C. to 500° C. for 0.5 to 4 hours, and the second calendering may be performed at a temperature of 120° C. to 140° C. with a load of 45 to 55 tons.

### Advantageous Effects

A heat dissipation sheet with excellent heat dissipation properties and a manufacturing method thereof of the present invention can exhibit excellent horizontal heat conductivity and an excellent effect in peel strength.

### DESCRIPTION OF DRAWINGS

FIG. 1 is a cross-sectional view of a heat dissipation sheet according to one embodiment of the present invention.

### MODES OF THE INVENTION

Hereinafter, the present invention will be described in more detail.

As described above, conventionally, electromagnetic interference (EMI) shielding heat shrinkable tapes, which are manufactured in a tape form for heat dissipation properties, use heat shrinkable tapes including a heat shrinkable layer and an EMI shielding layer. However, since a heat dissipation layer includes an adhesive layer in the conventional structure, heat dissipation efficiency is decreased, and a manufacturing process is complicated. Further, it is difficult to exhibit excellent horizontal heat conductivity and an excellent effect in peel strength.

Accordingly, the present invention seeks to solve the above-mentioned problem by providing a heat dissipation sheet with enhanced heat dissipation properties which includes a heat dissipation enhancing layer including carbon materials and a heat conductive base layer formed on one surface of the heat dissipation enhancing layer, and has a horizontal heat conductivity of 420 to 620 W/mK. Here, the carbon material includes at least one selected from graphene and graphite. Thus, unlike the conventional invention, the heat dissipation sheet of the present invention may have a specific porosity and exhibit excellent horizontal heat conductivity and excellent effect in peel strength.

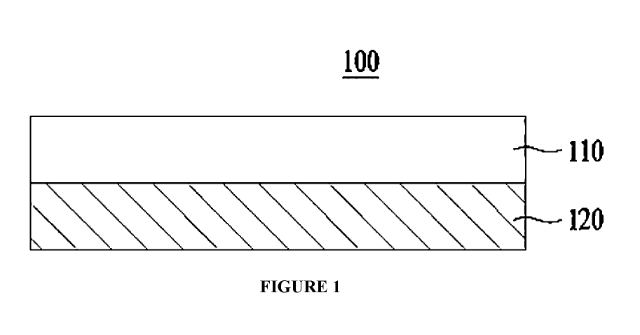

FIG. 1 is a cross-sectional view of a heat dissipation sheet according to one embodiment of the present invention, and illustrating a heat dissipation sheet 100 including a heat dissipation enhancing layer 110 and a heat conductive base layer 120 formed on one surface of the heat dissipation enhancing layer 110.

First, the heat dissipation enhancing layer 110 will be described.

The heat dissipation enhancing layer 110 serves to enhance the horizontal heat conductivity, and the horizontal heat conductivity may be excessively lowered when the heat dissipation enhancing layer 110 is not included.

Typically, a material for the heat dissipation enhancing layer 110 may be used without limitation as long as it is for enhancing the heat dissipation properties, and the heat dissipation enhancing layer 110 may preferably include a carbon material, and more preferably, include at least one selected from graphene and graphite.

In addition, typically, the heat dissipation enhancing layer 110 is not particularly limited as long as it is not too thick to enhance the horizontal heat conductivity, and preferably, the thickness may be in a range of 2 to 20 μm, and more preferably, the thickness may be in a range of 3 to 15 μm. When the thickness of the heat dissipation enhancing layer 110 is less than 2 μm, the enhancement of the horizontal heat conductivity may be insignificant, and when the thickness exceeds 20 μm, a phenomenon, in which the heat dissipation enhancing layer and the heat conductive base layer are peeled off, may occur.

Next, the heat conductive base layer 120 will be described.

The heat conductive base layer 120 is not limited as long as it is a heat conductive base layer that may be commonly used, preferably, may include a copper foil layer, and more preferably, may include at least one selected from an electrolytic copper foil and a rolled copper foil.

The heat conductive base layer 120 is not limited as long as it is not too thick for normal use in the heat dissipation sheet, and preferably, the thickness may be 13 to 40 μm, and more preferably, the thickness may be 15 to 38 μm. When the thickness of the heat conductive base layer 120 is less than 13 μm, the horizontal heat conductivity may be lowered, and when the thickness exceeds 40 μm, a peeling phenomenon may occur when subsequently applied to a product.

Meanwhile, the heat dissipation sheet 100 including the heat dissipation enhancing layer 110 and the heat conductive base layer 120 may have a horizontal heat conductivity of 420 to 620 W/mK, and preferably, a horizontal heat conductivity of 430 to 560 W/mK.

In addition, the heat dissipation enhancing layer may not include a binder resin. The horizontal heat conductivity of the heat dissipation sheet may be further increased by not including the binder resin.

Hereinafter, a method of manufacturing the heat dissipation sheet will be described.

The heat dissipation sheet is manufactured through a method of manufacturing a heat dissipation sheet having enhanced heat dissipation properties, including a process of manufacturing a heat dissipation enhancing coating liquid including a carbon material, a binder resin and a solvent, a process of applying the heat dissipation enhancing coating liquid on one surface of a heat conductive base layer to form a heat dissipation layer, a process of performing first calendering on the heat dissipation layer and the heat conductive base layer, a process of heat treating the first calendered heat dissipation layer and heat conductive base layer to form a heat dissipation enhancing layer and the heat conductive base layer, and a process of performing second calendering on the heat dissipation enhancing layer and the heat conductive base layer to manufacture the heat dissipation sheet.

First, the process of manufacturing the heat dissipation enhancing coating liquid will be described.

The heat dissipation enhancing coating liquid may include the carbon material, the binder resin, and the solvent.

The description of the carbon material is the same as that of the above-described carbon material and will be omitted.

The binder resin may include a first urethane resin having a solid content of 28 to 32 wt %, and preferably, a first urethane resin having a solid content of 29 to 31 wt %. When the solid content of the first urethane resin is less than 28 wt %, the heat dissipation enhancing coating liquid may be diluted, and the interlayer peeling phenomenon may subsequently occur, and when the solid content exceeds 32 wt %, the binder resin may still remain.

Also, the binder resin may include a second urethane resin having a solid content of 34 to 38 wt %, and preferably, a second urethane resin having a solid content of 34.5 to 36.5 wt %. When the solid content of the second urethane resin is less than 34 wt %, the heat dissipation enhancing coating liquid may be diluted, and the interlayer peeling phenomenon may subsequently occur, and when the solid content exceeds 38 wt %, the binder resin may still remain.

Further, the binder resin may include the first urethane resin and the second urethane resin in a weight ratio of 1:0.5 to 1:0.85, and preferably, in a weight ratio of 1:0.55 to 1:0.75. When the weight ratio of the first urethane resin to the second urethane resin is less than 1:0.5, an adhesion after calendering is degraded and a porosity is increased, and thus the horizontal heat conductivity may be lowered, and when the weight ratio exceeds 1:0.85, heat resistance may not be excellent.

The solvent is not particularly limited as long as it is a solvent capable of forming the heat dissipation layer, and preferably, may include toluene and ethyl acetate.

Also, the solvent may include toluene and ethyl acetate in a weight ratio of 1:0.7 to 1:1.4, and preferably, in a weight ratio of 1:0.8 to 1:1.2. When the weight ratio of the toluene to the ethyl acetate is less than 1:0.7, uniform mixing may not be achieved during stirring, and when the weight ratio exceeds 1:1.4, the ethyl acetate is rapidly vaporized in the solvent, and thus the content of the solvent may be relatively small.

The heat dissipation enhancing coating liquid may include 80 to 120 parts by weight of a binder resin and 180 to 220 parts by weight of a solvent based on 100 parts by weight of a carbon material, and preferably, 90 to 110 parts by weight of a binder resin and 190 to 210 parts by weight of a solvent based on 100 parts by weight of the carbon material. When the binder resin is less than 80 parts by weight based on 100 parts by weight of the carbon material, the interlayer peeling may subsequently occur, and when the binder resin exceeds 120 parts by weight, in a subsequent heat treatment process, all the binders are not burned and some remain, and thus the horizontal heat conductivity may not be excellent. Also, when the solvent is less than 180 parts by weight based on 100 parts by weight of the carbon material, it may be difficult to coat (apply) the heat conductive base layer with the solvent to an appropriate thickness, and when the solvent exceeds 220 parts by weight, a residual solvent may be generated even after the subsequent heat treatment process, and coating (applying) with the appropriate thickness may be difficult.

The process of manufacturing the heat dissipation enhancing coating liquid may include a process of mixing and stirring the carbon material, the binder resin, and the solvent for 30 to 60 minutes, and preferably, 30 to 50 minutes, to manufacture a mixed solution, and a process of stabilizing the mixed solution at a temperature of 20° C. to 30° C. for 30 to 60 minutes, and preferably, at a temperature of 22° C. to 28° C. for 40 to 50 minutes to manufacture the heat dissipation enhancing coating liquid.

When the time for mixing and stirring is less than 30 minutes, the mixing is not uniform and thus the distribution of components may not be uniform, and when the time exceeds 60 minutes, the solvent may be vaporized and thus the content of the solvent may be relatively small. When the temperature or time for the stabilization is less than 20° C. or less than 30 minutes, the mixed solution may not be stabilized easily, and when the temperature or time exceeds 30° C. or exceeds 60 minutes, the solvent may be vaporized and thus the content of the solvent may be relatively small.

Next, the process of applying the heat dissipation enhancing coating liquid on one surface of the heat conductive base layer to form the heat dissipation layer will be described.

The description of the heat conductive base layer is the same as that of the above-described heat conductive base layer and will be omitted.

In the process of forming the heat dissipation layer, the heat dissipation layer may be formed such that the thickness of the heat dissipation layer is 1.2 to 2.0 times, and preferably, 1.3 to 1.9 times the thickness of the heat dissipation enhancing layer in consideration of the reduced thickness due to the evaporation or burning of the solvent and the binder in the subsequent heat treatment and calendering processes. When the thickness of the heat dissipation layer is less than 1.2 times the thickness of the heat dissipation enhancing layer, the thickness of the heat dissipation enhancing layer may be smaller than a desired thickness, and when the thickness of the heat dissipation layer exceeds 2.0 times, the thickness of the heat dissipation enhancing layer may be greater than the desired thickness.

Next, the process of performing first calendering on the heat dissipation layer and the heat conductive base layer will be described.

The first calendering may be performed at a temperature of 60° C. to 80° C. with a load of 35 to 45 tons, and preferably, at a temperature of 65° C. to 75° C. with a load of 37 to 43 tons. When the load of the calendering is less than 35 tons, the peel strengths of the heat dissipation enhancing layer and the heat conductive base layer may be subsequently lowered, and when the load exceeds 45 tons, the heat conductive base layer may be damaged. When the temperature of the calendering is less than 60° C., the peel strengths of the heat dissipation enhancing layer and the heat conductive base layer may be subsequently lowered, and when the temperature exceeds 80° C., the heat dissipation enhancing layer may be adhered to a calendering roll during the calendering process to be peeled off from the base layer.

Next, the process of heat treating the first calendered heat dissipation layer and heat conductive base layer to form the heat dissipation enhancing layer and the heat conductive base layer will be described.

The heat treatment may be performed at a temperature of 400° C. to 500° C. for 0.5 to 4 hours, and preferably, at 430° C. to 470° C. for 1 to 3 hours. When the temperature of the heat treatment is less than 400° C., the binder resin may not burn well and thus the heat dissipation properties may not be excellent, and when the temperature exceeds 500° C., the temperature is excessively high and thus the peel strength may be lowered. When the time of the heat treatment is less than 0.5 hour, the binder resin may not burn well and thus the heat dissipation properties may not be excellent, and when the time exceeds 4 hours, the process time may be long.

Meanwhile, since the binder resin is burned through the heat treatment process, the heat dissipation enhancing layer formed after the heat treatment may not include the binder resin. When the heat dissipation enhancing layer includes the binder resin, the porosity may deviate from a desired range, and thus the heat dissipation properties may not be excellent.

Next, the process of performing second calendering on the heat dissipation enhancing layer and the heat conductive base layer to manufacture the heat dissipation sheet will be described.

The second calendering may be performed at a temperature of 120° C. to 140° C. with a load of 45 to 55 tons, and preferably, at a temperature of 125° C. to 135° C. with a load of 47 to 53 tons. When the load for performing the calendering is less than 45 tons, the peel strengths of the heat dissipation enhancing layer and the heat conductive base layer may be lowered, and when the load exceeds 55 tons, the heat conductive base layer may be damaged. Further, when the temperature of the calendering is out of the range, the peel strengths of the heat dissipation enhancing layer and the heat conductive base layer may be lowered.

Hereinafter, the present invention will be described with reference to the following examples. Here, the following examples are presented to illustrate the present invention, and the scope of the present invention is not limited by the following examples.

### Example 1

### Example 1: Manufacture of Heat Dissipation Sheet

### (1) Manufacture of Heat Dissipation Enhancing Coating Liquid

In order to manufacture a heat dissipation enhancing coating liquid, 100 parts by weight of a binder resin including a urethane resin having a solid content of 30 wt % and a urethane resin having a solid content of 35 wt % at a weight ratio of 1:0.67 based on 100 parts by weight of graphite powder having an average particle diameter of 5 μm, and 200 parts by weight of a solvent including toluene and ethyl acetate in a weight ratio of 1:1 were mixed and uniformly dispersed for 45 minutes using a high-speed stirrer to manufacture a mixed solution. Thereafter, the mixed solution was stabilized at a temperature of 25° C. for 45 minutes to manufacture the heat dissipation enhancing coating liquid.

### (2) Forming Heat Dissipation Layer

The heat dissipation enhancing coating liquid was applied on one surface of a heat conductive base layer using a comma coater (product name, company name) to a thickness of 7 μm to form a heat dissipation layer. For the heat conductive base layer, an electrolytic copper foil having a thickness of 35 μm was used.

### (3) Manufacture of Heat Dissipation Sheet

The heat dissipation layer and the heat conductive base layer were first calendered using a roll press at 70° C. with a load of 40 tons to enhance an interlayer adhesion, and the first calendered heat dissipation layer and heat conductive base layer were heat-treated at 450° C. for 2 hours to burn the binder resin included in the heat dissipation layer, thereby forming the heat dissipation enhancing layer.

The heat dissipation enhancing layer and the heat conductive base layer were second calendered using the roll press at a temperature of 130° C. with a load of 50 tons to enhance the interlayer adhesion once again. After completion of the manufacturing process, the thickness of the heat dissipation enhancing layer was 5 μm, and the total thickness of the heat dissipation sheet was 40 μm.

### Examples 2 to 22 and Comparative Examples 1 to 6

The heat dissipation sheet was manufactured in the same manner as in Example 1 except that the type of a carbon material, the content of a binder, the type and thickness of the heat conductive base layer, and process conditions were changed as shown in Table 1 below.

TABLE 1

| | Heat dissipation | | | | | | |
|---|---|---|---|---|---|---|---|
| | enhancing layer | | | | | | |
| | | Binder resin | | Heat conductive | | Heat treatment | |
| | Carbon | Content | | base layer | | process | Whether |
| | material | (Parts by | Weight | Thickness | | Temperature | calendered |
| Type | (Type) | Weight)¹⁾ | ratio | (μm) | Type | (° C.) | or not |
| Example 1 | Graphite | 100 | 1:0.67 | 35 | Electrolytic | 450 | ∘ |
| | | | | | copper foil | | |
| Example 2 | Graphite | 75 | 1:0.67 | 35 | Electrolytic | 450 | ∘ |
| | | | | | copper foil | | |
| Example 3 | Graphite | 85 | 1:0.67 | 35 | Electrolytic | 450 | ∘ |
| | | | | | copper foil | | |
| Example 4 | Graphite | 115 | 1:0.67 | 35 | Electrolytic | 450 | ∘ |
| | | | | | copper foil | | |
| Example 5 | Graphite | 125 | 1:0.67 | 35 | Electrolytic | 450 | ∘ |
| | | | | | copper foil | | |
| Example 6 | Graphite | 100 | 1:0.67 | 10 | Electrolytic | 450 | ∘ |
| | | | | | copper foil | | |
| Example 7 | Graphite | 100 | 1:0.67 | 45 | Electrolytic | 450 | ∘ |
| | | | | | copper foil | | |
| Example 8 | Graphite | 100 | 1:0.67 | 35 | Electrolytic | 390 | ∘ |
| | | | | | copper foil | | |
| Example 9 | Graphite | 100 | 1:0.67 | 35 | Electrolytic | 410 | ∘ |
| | | | | | copper foil | | |
| Example 10 | Graphite | 100 | 1:0.67 | 35 | Electrolytic | 490 | ∘ |
| | | | | | copper foil | | |
| Example 11 | Graphite | 100 | 1:0.67 | 35 | Electrolytic | 510 | ∘ |
| | | | | | copper foil | | |
| Example 12 | Graphite | 100 | 1:0.67 | 18 | Electrolytic | 450 | ∘ |
| | | | | | copper foil | | |
| Example 13 | Graphite | 100 | 1:0.67 | 25 | Rolled | 450 | ∘ |
| | | | | | copper foil | | |
| Example 14 | Graphite | 100 | 1:0.67 | 16.5 | Rolled | 450 | ∘ |
| | | | | | copper foil | | |
| Example 15 | Graphene | 100 | 1:0.67 | 35 | Electrolytic | 450 | ∘ |
| | | | | | copper foil | | |
| Example 16 | Graphene | 100 | 1:0.67 | 18 | Electrolytic | 450 | ∘ |
| | | | | | copper foil | | |
| Example 17 | Graphene | 100 | 1:0.67 | 25 | Rolled | 450 | ∘ |
| | | | | | copper foil | | |
| Example 18 | Graphene | 100 | 1:0.67 | 16.5 | Rolled | 450 | ∘ |
| | | | | | copper foil | | |
| Example 19 | Graphite | 100 | 1:0.45 | 35 | Electrolytic | 450 | ∘ |
| | | | | | copper foil | | |
| Example 20 | Graphite | 100 | 1:0.55 | 35 | Electrolytic | 450 | ∘ |
| | | | | | copper foil | | |
| Example 21 | Graphite | 100 | 1:0.80 | 35 | Electrolytic | 450 | ∘ |
| | | | | | copper foil | | |
| Example 22 | Graphite | 100 | 1:0.90 | 35 | Electrolytic | 450 | ∘ |
| | | | | | copper foil | | |
| Comparative | — | — | | 35 | Electrolytic | — | — |
| Example 1 | | | | | copper foil | | |
| Comparative | — | — | | 18 | Electrolytic | — | — |
| Example 2 | | | | | copper foil | | |
| Comparative | — | — | | 25 | Rolled | — | — |
| Example 3 | | | | | copper foil | | |
| Comparative | — | — | | 16.5 | Rolled | — | — |
| Example 4 | | | | | copper foil | | |
| Comparative | Graphite | 100 | | 35 | Electrolytic | — | ∘ |
| Example 5 | | | | | copper foil | | |
| Comparative | Graphite | 100 | | 35 | Electrolytic | 450 | x |
| Example 6 | | | | | copper foil | | |

¹⁾The parts by weight are the parts by weight of the binder based on 100 parts by weight of the carbon material.

### Experimental Example

Physical properties of the heat dissipation sheets manufactured through the above-described Examples and Comparative Examples were measured and are shown in Table 2 below.

### 1. Peel Strength Measurement

The peel strengths of the heat dissipation sheets manufactured through the above-described Examples and Comparative Examples were measured at room temperature (25° C.) using an all-purpose material testing machine (H5KT, Tinius Olsen).

### 2. Horizontal Heat Conductivity Measurement

The horizontal heat conductivity of each of the heat dissipation sheets manufactured through the above-described Examples and Comparative Examples was measured by a laser flash method using a heat conductivity meter (LFA, NETZSCH).

TABLE 2

| | Peel | Horizontal heat |
|---|---|---|
| Type | strength (N/m²) | conductivity (W/mK) |
| Example 1 | • | 497 |
| Example 2 | ▴ | 412 |
| Example 3 | • | 422 |
| Example 4 | • | 421 |
| Example 5 | ∘ | 398 |
| Example 6 | • | 401 |
| Example 7 | ▴ | 481 |
| Example 8 | • | 387 |
| Example 9 | • | 431 |
| Example 10 | • | 440 |
| Example 11 | ▴ | 481 |
| Example 12 | • | 441 |
| Example 13 | • | 498 |
| Example 14 | • | 475 |
| Example 15 | • | 602 |
| Example 16 | • | 498 |
| Example 17 | • | 589 |
| Example 18 | • | 550 |
| Example 19 | ▴ | 402 |
| Example 20 | • | 422 |
| Example 21 | • | 431 |
| Example 22 | ▴ | 419 |
| Comparative Example 1 | — | 344 |
| Comparative Example 2 | — | 313 |
| Comparative Example 3 | — | 356 |
| Comparative Example 4 | — | 329 |
| Comparative Example 5 | ∘ | 376 |
| Comparative Example 6 | x | 412 |

•—Very High,
∘—High,
▴—Medium,
x—Low

As can be seen from the above-described Table 2, Examples 1, 3, 4, 9, 10, 12 to 18, 20, and 21 of the present invention, which satisfy all the types of the carbon material, the content of the binder, the type and thickness of the heat conductive base layer, the process conditions, and the like, had excellent peel strength and excellent horizontal heat conductivity as compared with Examples 2, 5, 6, 7, 8, 11, 19, 22, and 1 to 6 in which at least one of the type of the carbon material, the content of the binder, the type, and thickness of the heat conductive base layer, the process conditions, and the like is omitted.

### DESCRIPTION OF REFERENCE NUMERALS

100: HEAT DISSIPATION SHEET
110: HEAT DISSIPATION ENHANCING LAYER
120: HEAT CONDUCTIVE BASE LAYER

1. A heat dissipation sheet having enhanced heat dissipation properties, comprising:
a heat dissipation enhancing layer including a carbon material; and
a heat conductive base layer formed on one surface of the heat dissipation enhancing layer,
wherein the carbon material includes at least one selected from graphene and graphite, and
horizontal heat conductivity is in a range of 420 W/mK to 620 W/mK.

2. The heat dissipation sheet of claim 1, wherein the heat dissipation enhancing layer does not include a binder resin.

3. The heat dissipation sheet of claim 1, wherein the heat dissipation enhancing layer has a thickness of 2 to 20 μm, and the heat conductive base layer has a thickness of 13 to 40 μm.

4. The heat dissipation sheet of claim 1, wherein the heat conductive base layer includes at least one selected from an electrolytic copper foil and a rolled copper foil.

5. A method of manufacturing a heat dissipation sheet having enhanced heat dissipation properties, comprising:
a process of manufacturing a heat dissipation enhancing coating liquid including a carbon material, a binder resin, and a solvent;
a process of applying the heat dissipation enhancing coating liquid on one surface of a heat conductive base layer to form a heat dissipation layer;
a process of performing first calendering on the heat dissipation layer and the heat conductive base layer;
a process of heat treating the first calendered heat dissipation layer and heat conductive base layer to form a heat dissipation enhancing layer and the heat conductive base layer; and
a process of performing second calendering on the heat dissipation enhancing layer and the heat conductive base layer to manufacture the heat dissipation sheet.

6. The method of claim 5, wherein the binder resin includes a first urethane resin having a solid content of 28 to 32 wt % and a second urethane resin having a solid content of 34 to 38 wt %.

7. The method of claim 6, wherein the binder resin includes the first urethane resin and the second urethane resin in a weight ratio of 1:0.5 to 1:0.85.

8. The method of claim 5, wherein the process of manufacturing the heat dissipation enhancing coating liquid includes:
a process of mixing and stirring 80 to 120 parts by weight of a binder resin and 180 to 220 parts by weight of a solvent based on 100 parts by weight of a carbon material for 30 to 60 minutes to manufacture a mixed solution; and
a process of stabilizing the mixed solution at a temperature of 20° C. to 30° C. for 30 to 60 minutes to manufacture the heat dissipation enhancing coating liquid.

9. The method of claim 5, wherein the solvent includes toluene and ethyl acetate in a weight ratio of 1:0.7 to 1:1.4, and
the heat conductive base layer includes at least one selected from an electrolytic copper foil and a rolled copper foil.

10. The method of claim 5, wherein, in the process of forming the heat dissipation layer,
the heat dissipation layer is formed such that a thickness of the heat dissipation layer is 1.2 to 2.0 times the thickness of the heat dissipation enhancing layer.

11. The method of claim 5, wherein the heat dissipation enhancing layer does not include the binder resin.

12. The method of claim 5, wherein the first calendering is performed at a temperature of 60° C. to 80° C. with a load of 35 to 45 tons,
the heat treatment is performed at a temperature of 400° C. to 500° C. for 0.5 to 4 hours, and
the second calendering is performed at a temperature of 120° C. to 140° C. with a load of 45 to 55 tons.
